(19) United States
(12) Patent Application Publication
(10) Pub. No.: US 2011/0109397 A1
(43) Pub. Date: May 12, 2011

(54) RADIOFREQUENCY OSCILLATOR

(75) Inventors: Bertrand Delaet, Bernin (FR); Ursula Ebels, Grenoble (FR)

(73) Assignees: Commissariat a I'energie atomique et aux energies alternatives, Paris (FR); Centre National De La Researche Scientifique, Paris (FR)

(21) Appl. No.: 12/916,858

(22) Filed: Nov. 1, 2010

(30) Foreign Application Priority Data
Nov. 6, 2009 (FR) 0957888

(51) Int. Cl. H03B 5/40

(52) U.S. Cl. 331/157

(57) ABSTRACT

This radiofrequency oscillator has a free layer (10) and/or a reference layer formed by a stacking of at least three ferromagnetic or ferrimagnetic layers coupled to one another by an RKKY (Ruderman-Kittel-Kasuya-Yosida) coupling and among which at least two sub-layers are magnetically coupled to each other by an antiferromagnetic RKKY coupling.

### CROSS-REFERENCE TO RELATED APPLICATIONS

Under 35 USC 119, this application claims the benefit of the Nov. 6, 2009 priority date of French Application No. FR0957888, the content of which are hereby incorporated by reference in their entirety.

### BACKGROUND

The invention pertains to a radiofrequency oscillator.

More specifically, the invention pertains to a radiofrequency oscillator integrating a magnetoresistive device within which a spin-polarised electrical current flows. In such an oscillator, the passage of the current prompts a periodic variation in the resistance of the magnetoresistive device. A high-frequency signal, i.e. one whose frequency typically ranges from 100 MHz to some tens of GHz, is created from this periodic variation. The period of the variations of the resistivity and therefore the oscillation frequency may be adjusted by playing on the intensity of the current that crosses the magnetoresistive device and/or the external magnetic field.

Such oscillators are designed for example for use in radiotelevision communications because they can generate a wide range of frequencies with a high quality factor.

The term “quality factor” designates the following ratio:

Q=f/Δf

where:

Q is the quality factor,

f is the oscillation frequency of the oscillator, and

Δf is the width at mid-height of the line centered on the frequency fin the power spectrum of this oscillator.

Certain radiofrequency oscillators are derived from spin electronics.

Spin electronics uses the spin of the electrons as an additional degree of freedom in order to generate novel effects. The spin polarization of an electrical current results from the asymmetry existing between the diffusion of the spin-up type conduction electrons (i.e. electrons parallel to the local magnetization) and spin-down type conduction electrons (i.e. electrons anti-parallel to the local magnetization). This asymmetry leads to an asymmetry in the conductivity between the two spin-up and spin-down channels, whence a sharp spin polarization of the electrical current.

This spin polarization of the current is the source of magnetoresistive phenomena in magnetic multi-layers such as giant magnetoresistance (Baibich, M., Broto, J. M., Fert, A., Nguyen Van Dau, F., Petroff, F., Etienne, P., Creuzet, G., Friederch, A. and Chazelas, J., “Giant magnetoresistance of (001)Fe/(001)Cr magnetic superlattices”, Phys. Rev. Lett., 61 (1988) 2472), or tunnel magnetoresistance (Moodera, J S., Kinder, L R., Wong, T M. and Meservey, R. “Large magnetoresistance at room temperature in ferromagnetic thin-film tunnel junctions”, Phys. Rev. Lett 74, (1995) 3273-6).

Furthermore, it has also been observed that by making a spin-polarized current pass through a thin magnetic layer, it is possible to induce a reversal of its magnetization when there is no external magnetic field (Katine, J. A., Albert, F. J., Buhrman, R. A., Myers, E. B., and Ralph, D. C., “Current-Driven Magnetization Reversal and Spin-Wave Excitations in Co/Cu/Co Pillars”, Phys. Rev. Lett. 84, 3149 (2000).

Polarized current can also generate sustained magnetic excitations, known especially as oscillations (Kiselev, S. I., Sankey, J. C., Krivorotov, L N., Emley, N. C., Schoelkopf, R. J., Buhrman, R. A., and Ralph, D. C., “Microwave oscillations of a nanomagnet driven by a spin-polarized current”, Nature, 425, 380 (2003)). The use of the effect of the generation of sustained magnetic excitations on a magnetoresistive device enables the conversion of this effect into modulation of electrical resistance directly usable in electronic circuits and therefore liable, as a corollary, to intervene directly at the frequency level. The U.S. Pat. No. 5,695,864 describes various developments implementing the physical principle mentioned here above. It describes especially the precession of the magnetization of a magnetic layer crossed by a spin-polarized electrical current. The physical principles implemented as well as the terminology used are also described and defined in the patent application number FR 2 892 871.

The oscillation frequency of these radiofrequency oscillators is adjusted by playing on the intensity of the current that crosses it and, if necessary, also on an external magnetic field.

There is a radiofrequency oscillator known from the application FR 2 892 871 comprising a stack of at least:

a first magnetic layer known as a “reference layer” that is capable of spin-polarizing the electrical current and has magnetization with a fixed direction,

a second magnetic layer, called a free layer, whose magnetization can oscillate when it is crossed by the spin-polarized current,

a non-magnetic layer, known as a spacer, interposed between the two preceding layers and designed to magnetically uncouple said first and second magnetic layers, and

means to make an electron current flow in said layers perpendicularly to these layers.

The patent application FR 2 892 871 teaches that, to improve the consistency of precession, it is advantageous to make the free layer using a stack of ferromagnetic sublayers constituting a synthetic anti-ferromagnetic.

The term “consistency of precession” designates the fact that the magnetization is set into motion all together as one block throughout the extension of the current sheet crossing the structure (i.e. on the section of the pillar in the pillar geometry and on the section of the current cone at the free layer in the case of the nanocontact geometry) as opposed to the generation of numerous small mutually inconsistent excitations.

The term “synthetic antiferromagnetic” (SAF) or artificial antiferromagnetic designates a stack of at least two ferromagnetic sub-layers, each layer being magnetically coupled with each adjacent ferromagnetic sublayer by an RKKY (Ruderman-Kittel-Kasuya-Yosida) antiferromagnetic coupling. Furthermore, the ferromagnetic sublayers of a synthetic antiferromagnetic are sized so that the overall magnetization of the synthetic antiferromagnetic is zero when there is no external magnetic field.

To obtain RKKY coupling, the ferromagnetic sublayers are separated from one another by thin non-magnetic sublayers.

Depending on the thickness of the non-magnetic sublayer, the RKKY coupling obtained is:

either “antiferromagnetic”, i.e. the magnetic moments of the two coupled sublayers are anti-parallel,

or “ferromagnetic” i.e. the magnetic moments of the two coupled sublayers are parallel.

In a synthetic antiferromagnetic, the thickness of the non-magnetic sublayer or sublayers is routinely chosen to obtain an antiferromagnetic RKKY coupling.

For further information on RKKY coupling, reference may be made to the following two articles: S. Parkin et al., Physical Review B 44 N^{o} 13 (1991) and S. Parkin et al. Physical Review Letters 64 N^{o} 19 (1990).

To obtain a comprehensively zero magnetization, the magnetic moments of each ferromagnetic sublayer compensate for one another mutually. For example, in the case of a synthetic antiferromagnetic with two ferromagnetic sublayers, the following relationship is verified:

(M1*t1−M2*t2)/(t1+t2)=0

where:

M1 and t1 are respectively the magnetic moment and the thickness of the first magnetic layer, and

M2 and t2 are respectively the magnetic moment and the thickness of the second magnetic layer.

A synthetic antiferromagnetic is a particular synthetic ferrimagnetic. Synthetic ferrimagnetics are known by the acronym SYF. A synthetic ferrimagnetic is a stack of at least two ferromagnetic or ferrimagnetic sublayers coupled with one another through a non-magnetic layer by means of an RKKY anti-ferromagnetic coupling. Unlike in the case of the synthetic ferromagnetic, the resultant magnetization of the stack is not necessarily zero.

The term non-magnetic layer or material designates a layer or material that does not have any measurable magnetization in a zero field. It can therefore be a material having no magnetic property, an amagnetic material or a diamagnetic material or a paramagnetic material.

The patent application FR 2 892 871 describes the use of a synthetic antiferromagnetic to form the free layer of the radiofrequency oscillator. This synthetic antiferromagnetic is formed solely by two ferromagnetic sublayers.

### SUMMARY

The invention proposes a radiofrequency oscillator having an improved quality factor. An object of the invention therefore is a radiofrequency oscillator in which the free layer and/or the reference layer are formed by a stack of at least three ferromagnetic or ferrimagnetic sublayers coupled to one another by RKKY (Ruderman-Kittel-Kasuya-Yosida) coupling, and among which two sublayers are magnetically coupled to one another by an antiferromagnetic RKKY coupling.

It has been noted that the mid-heigh width Δf of the radiofrequency oscillator at the oscillation frequency f is inversely proportional to the volume (here below called the effective volume and denoted as V_{eff}) of the magnetic material of the free layer or of the reference layer. The making of the free layer or of the reference layer by means of a stack of at least three ferromagnetic or ferrimagnetic sublayers magnetically coupled to one another by RKKY coupling increases the effective volume of this layer.

Indeed, the effective volume of the free layer or reference layer corresponds to the sum of the volumes of each ferromagnetic or ferrimagnetic sublayer that forms it. This increase in the effective volume decreases the mid-heigh width Δf and therefore improves the quality factor of this oscillator.

Furthermore, the fact of making the free layer or reference layer in the form of a stack of sublayers magnetically coupled by RKKY coupling causes the reduction in the mid-heigh width Δf to take place:

without in any way degrading or even improving the consistency of precession sustained in this layer, and

without changing or even diminishing the intensity of the critical current I_{c} needed to activate the sustained oscillations of the oscillator.

The embodiments of this radiofrequency oscillator can also comprise one or more of the following characteristics:

each ferromagnetic or ferrimagnetic sublayer of the stack is coupled to the ferromagnetic or ferrimagnetic sublayer placed immediately above by an anti-ferromagnetic RKKY coupling so that the stack is a synthetic ferrimagnetic;

wherein the sublayers are ferromagnetic sublayers and the magnetic moments of each ferromagnetic sublayer compensate for one another mutually so that the stack is a synthetic antiferromagnetic;

at least two ferromagnetic or ferrimagnetic sublayers are coupled to each other by an antiferromagnetic RKKY coupling and at least two ferromagnetic or ferrimagnetic sublayers are coupled to each other by a ferromagnetic RKKY coupling;

the stacking of the ferromagnetic or ferrimagnetic sublayers is formed solely by three ferromagnetic or ferrimagnetic sublayers;

the thickness of a first ferromagnetic or ferrimagnetic sublayer closest to the non magnetic layer is smaller than 10 nm and advantageously ranges between 1 and 4 nm;

at least the free layer is formed by the stacking of at least three ferromagnetic sublayers coupled to one another by an RKKY (Ruderman-Kittel-Kasuya-Yosida) coupling;

the oscillator has an antiferromagnetic layer in direct contact with the reference layer to trap its magnetization, and

the reference layer is a synthetic antiferromagnetic.

These embodiments of the radiofrequency oscillator furthermore have the following advantages:

using a stack for which the overall magnetic moment is appreciably zero increases the stability of the oscillator by reducing or even eliminating the dipolar field radiated on the other magnetic layers,

the fact that the thickness of the first ferromagnetic sublayer is smaller than 4 nm diminishes the intensity of the critical current I_{c}. Indeed, this current is directly proportional to the thickness of the first layer, and

trapping the reference layer with an antiferromagnetic layer or making the reference layer by means of a synthetic antiferromagnetic layer increases the stability of the magnetization of the reference layer.

### BRIEF DESCRIPTION OF THE DRAWINGS

The invention will be understood more clearly from the following description, given purely by way of a non-restrictive example and made with reference to the appended drawings, of which:

FIG. 1 is a schematic illustration of a radiofrequency oscillator,

FIGS. 2 to 5 are schematic illustrations of other embodiments of the radiofrequency oscillator of FIG. 1,

FIG. 6 is a schematic illustration of a synthetic antiferromagnetic that can be implemented, to make any one of the oscillators of FIGS. 1 to 5, and

FIG. 7 is a schematic illustration of a stack of ferromagnetic sublayers that can be implemented to make any one of the oscillators of FIGS. 1 to 5.

In these figures, the same references are used to designate the same elements.

### DETAILED DESCRIPTION

Here below in this description, the characteristics and functions well known to those skilled in the art shall not be described in detail.

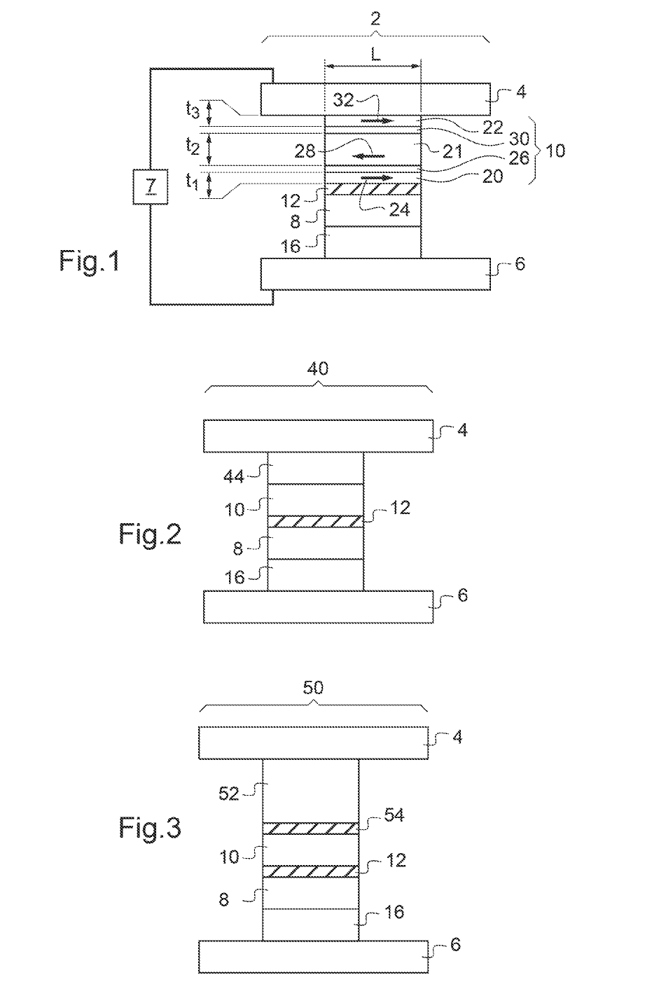

FIG. 1 shows a radiofrequency oscillator 2. This oscillator 2 integrates a magnetoresistive device within which there flows a spin-polarized electrical current. This magnetoresistive device is shaped according to a geometry known as CCP (current perpendicular to plane geometry). More specifically, in FIG. 1, the magnetoresistive device takes what is called a “nanopillar” structure. This nanopillar is formed by stacking horizontal layers having the same horizontal section on top of one another.

Furthermore, the oscillator 2 has a conductive electrode, respectively 4 and 6, at each end of the pillar. These electrodes are used to convey the current that crosses the different layers forming the magnetoresistive device perpendicularly to the plane of these layers. When the intensity of this current exceeds the intensity of the critical current I_{c}, the voltage between these electrodes 4 and 6 starts oscillating at a frequency which depends on the current crossing the electrodes. For example, this voltage is transmitted to an electronic apparatus 7 which processes it in order to create for example a reference signal.

Between these electrodes 4 and 6, the pillar has chiefly three layers, namely a reference layer 8, a free layer 10 and a non-magnetic layer 12 interposed between the layers 8 and 10. The non-magnetic layer is better known as a spacer.

These layers 8, 10 and 12 are laid out and shaped so as to enable the appearance of magnetoresistive properties, i.e. a variation in the resistance of the pillar as a function of the directions of magnetization of the layers 8 and 10.

The width L of the different layers forming the pillar is constant. Here, the width L is smaller than 1 μm and typically ranges from 20 nm to 200 nm.

The reference layer 8 is made out of an electrically conductive magnetic material. Its upper face is in direct contact with the spacer 12. It has a direction of easier magnetization contained in the plane of the layer.

The reference layer 8 has the function of spin-polarizing the electrons of the current that crosses it. It therefore has a thickness sufficient to fulfill this function. Typically, the thickness of the reference layer 8 is strictly greater than the spin-diffusion length (see for example the patent application FR2892871 for a definition of this term).

For example, the reference layer 8 is made out of cobalt (Co), nickel (Ni), iron(Fe) or their alloys (CoFe, NiFe, CoFeB . . . etc.). The thickness of the reference layer 8 is of the order of some nanometers. The reference layer 8 may be laminated by the insertion of a few (typically 2 to 4) very thin layers of copper, silver or gold with a thickness of the order of 0.2 to 0.5 nm to reduce the spin-diffusion length. It is also possible for the layer 8 to be made of either an SYF or an SAF. To improve the readability of FIG. 1, the proportions between the thicknesses of the different layers have not been maintained.

Here, the reference layer 8 has a magnetization whose direction is fixed. The term “fixed-direction magnetization” designates the fact that it is more difficult to modify the direction of the magnetic moment of the reference layer 8 than the direction of the magnetic moment of the free layer 10. To obtain this, the magnetization of the reference layer 8 is for example trapped by a conductive antiferromagnetic layer 16 interposed between the reference layer 8 and the electrode 6. The upper face of the layer 16 is for example in direct contact with the lower face of the reference layer 8.

Typically, the thickness of the layer 16 layer ranges from 5 to 50 nm. It can be made out of a manganese alloy such as one of the following alloys IrMn, PtMn, FeMn, etc. For example, this layer 16 is made out of a material chosen in the group comprising IrMn, FeMn, PtMn, NiMn.

The spacer 12 is a non-magnetic layer. This spacer 12 is thin enough to enable the spin-polarized current to pass from the reference layer 8 to the free layer 10 in restricting polarization loss. Conversely, the thickness of this spacer 12 is big enough to provide for magnetic decoupling between the layers 8 and 10.

For example, the spacer 12 is made out of an electrically conductive material such as copper (Cu). The magnetoresistive properties of the pillar are then qualified as a giant magnetoresistance (GMR) qualities. In this instance, the thickness of the spacer 12 is typically greater than 2 nm. Generally, its thickness ranges from 2 to 40 nm and is preferably equal to 5 nm±25%.

The spacer 12 can also be made out of an insulator material such as an oxide or an aluminum nitride, a magnesium oxide, tantalum nitride, strontium titanate (SrTiO₃), etc. The pillar then has tunnel magnetoresistance (TMR) properties. In this case, the thickness of the spacer 12 typically ranges from 0.5 nm to 3 nm.

The free layer 10 is an electrically conductive magnetic layer, the magnetization of which can rotate or “precess” more easily than the magnetization of the reference layer 8.

Here, this free layer 10 is made by the stacking of three ferromagnetic sublayers 20 to 21. The sublayers 20, 21 and 21, 22 are coupled to each other by an antiferromagnetic RKKY coupling. The stack of sublayers 20 to 22 is therefore a synthetic ferrimagnetic. The direction of easier magnetization of these sublayers is included in the plane of the sublayers.

The lower face of the sublayer 20 is in direct contact with the upper face of the spacer 12. The thickness t₁ of the sublayer 20 is as small as possible. Indeed, the more restricted this thickness t₁, the smaller is the critical current I_{c}. For example, the thickness t₁ ranges from 1 nm to 6 nm and preferably from 1 nm to 4 nm.

This sublayer 20 is made out of a ferromagnetic material such as cobalt, nickel or iron or out of an alloy of these different metals (for example CoFe, CoFeB, NiFe etc.).

When there is no spin-polarized current or external magnetic field current, the overall magnetic moment of the sublayer 20 is oriented in parallel to the plane of this sublayer. The direction of this magnetic moment is represented by an arrow 24 in FIG. 1.

The amplitude of the magnetic moment of the sublayer 20 is proportional to the magnetization M₁ of the ferromagnetic material used for this sublayer multiplied by the thickness t₁. The sublayer 20 occupies a volume V₁. The magnetic moment m is equal to the product of the magnetization M₁ by this volume V₁ and is therefore proportional to the product M₁*t₁.

To obtain an RKKY coupling between the sublayers 20 and 21, a non-magnetic conductive sublayer 26 is directly interposed between these two sublayers 20 and 21. The thickness of this sublayer 26 is small enough for the ferromagnetic sublayers 20 and 21 to be coupled antiferromagnetically. The term “antiferromagnetic coupling” indicates the fact that the magnetic moments of the sublayers 20 and 21 are antiparallel.

For example, the sublayer 26 is made out of a material such as ruthenium (Ru), rhenium (Re), copper (Cu), chromium (Cr), platinum (Pt) or silver (Ag). Depending on the material chosen to make the sublayer 26, its thickness used to obtain an RKKY coupling is not the same. For example, if the sublayer 26 is made of chromium, the thickness is smaller than or equal to 4.5 nm. If the sublayer 26 is made of copper, the thickness is smaller than 1.5 nm.

Preferably, the thickness of the sublayer 26 is a few angstroms, i.e. ranging from 1 to 50 angströms. For example the thickness here is 8 angströms.

The lower face of the sublayer 21 is directly deposited on the sublayer 26. This sublayer 21 is magnetically coupled by an antiferromagnetic RKKY coupling to the sublayers 20 as well as 22. The direction of its magnetic moment, represented by an arrow 28, is therefore opposite that of the magnetic moment of the sublayers 20 and 22.

In this embodiment, the thickness t₂ of the sublayer 21 is chosen to be strictly greater than the thickness t₁ so as to even further increase the effective volume V_{eff} of the free layer 10. Indeed, the greater the increase in the effective volume V_{eff} of the free layer 10, the greater the reduction in the mid-heigh width Δf. For example, the thickness t₂ is chosen so that the volume V₂ of the sublayer 21 is greater than the volume V₁ of the sublayer 20 by at least 10% or even 25%.

Furthermore, here, the sublayer 21 is designed to cancel the magnetic moments of the sublayers 20 and 22 so as to obtain a synthetic antiferromagnetic. The use of a compensated synthetic antiferromagnetic to make the free layer 10 increases the stability of the oscillator by reducing the dipolar field radiated on the other magnetic layers.

In the particular case described here, the sublayer 21 is made out of the same antiferromagnetic material as the sublayers 20 and 22. Its magnetic moment is therefore proportional to the magnetization M₁ multiplied by the thickness t₂. This means that to cancel the magnetic moments of the sublayers 20 and 22, the thickness t₂ is chosen to be equal to twice the thickness t₁.

A conductive non-magnetic sublayer 30 is interposed between the sublayers 21 and 22, so as to obtain the antiferromagnetic RKKY coupling between these two sublayers. For example, the sublayer 30 is identical to the sublayer 26.

The lower face of the sublayer 22 is in direct contact with the upper face of the sublayer 30. The sublayer 22 is identical for example to the sublayer 20. The direction of its magnetic moment is herein represented by an arrow 32.

FIG. 2 shows a radiofrequency oscillator 40 identical to the radiofrequency oscillator 2 except that a layer 44 of antiferromagnetic material is deposited on the free layer 10. The layer 44 is therefore interposed between, on the one hand, the electrode 4 and, on the other hand, the free layer 10. For example, this layer 44 is made out of a material identical to those that can be used for the layer 16. This layer 44 degrades the relative freedom of magnetization of the free layer 10. However, by playing on the thickness of this layer 44, it is possible to ensure that the magnetic coupling implemented is smaller than that implemented in the reference layer 8 and the antiferromagnetic layer 16. Thus, the magnetization of the free layer 10 nevertheless manages to precess and the coupling inherent in the antiferromagnetic layer 44 contributes to maintaining the consistency of this magnetization.

FIG. 3 represents a radiofrequency oscillator 50 identical to that of FIG. 2 except that the layer 44 is replaced by a polarizer 52 separated from the free layer 10 by a spacer 54. A polarizer is a layer or a magnetic multilayer whose magnetization is outside the plane of the layer and preferably perpendicular to the plane of the layer. The polarizer spin-polarizes the current that crosses it. Typically, the polarizer is formed by several sublayers superimposed on each other, for example an alternation of magnetic and metal layers (for example (Co/POt)ₙ). Here, the polarizer is not described in greater detail. For further information on the polarizers, reference may be made to the patent application FR2817 998.

Here, the polarizer 52 is directly deposited beneath the electrode 4. The magnetic moment of this polarizer is perpendicular to the plane of the layers.

The spacer 54 is deposited directly beneath the polarizer 52. This spacer fulfils the same functions as the spacer 12.

The presence of the polarizer is used to obtain a precession of the magnetization of the free layer 10 outside its plane. This makes it possible for example to cause this oscillator to work in a zero field, i.e. when there is no external magnetic field.

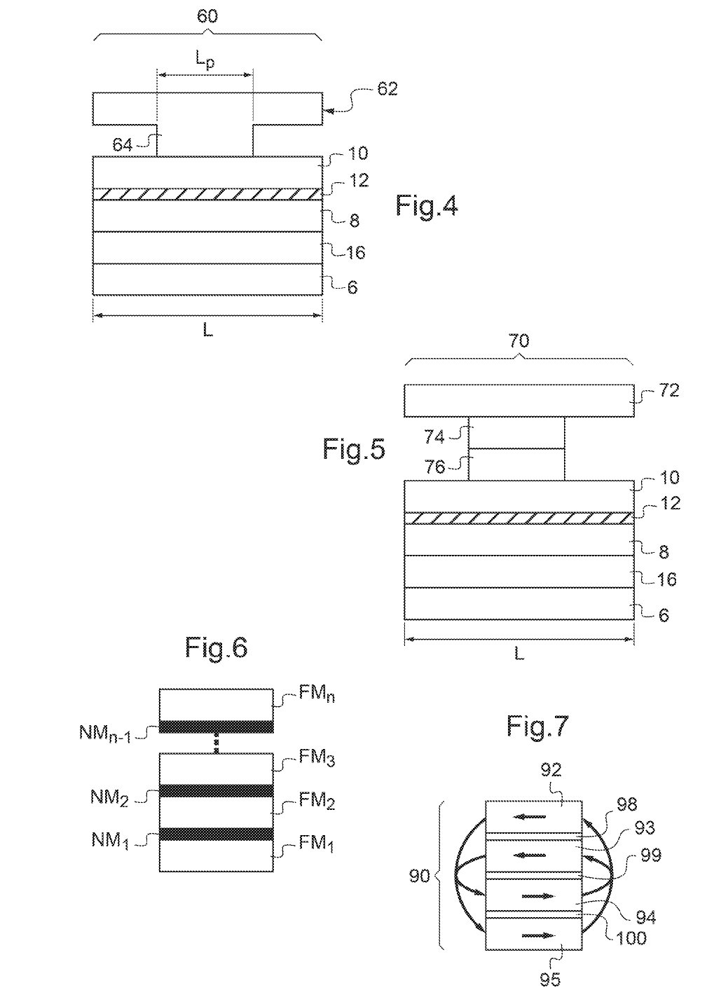

FIG. 4 represents a radiofrequency oscillator 60 whose quality factor is improved by using the same teachings as those given with reference to FIG. 1. However, the oscillator 60 is made according to a structure known as a “nanocontact” or “point contact” stack.

Structures such as this one are described in the patent application FR 2 892 871. It shall therefore not be described here in greater detail.

The oscillator 60 is therefore identical to the oscillator 2 except that the electrode 4 is replaced by an electrode 62.

The electrode 6, as well as the layers 8, 10, 12 and 16 have the same horizontal section with a width L. This width L is typically greater than 100 nm. It may attain several microns.

The electrode 62 has a tip 64 with a width Lₚ in direct contact with the upper face of the free layer 10. The width Lₚ is strictly smaller than the width L in such a way that the electrons of the current that flows between the electrodes 4 and 6 is distributed essentially in a cone in the stack of the layers 8, 10, 12 and 16. Preferably, the width Lₚ is several times smaller (for example five times smaller) than the width L. For example, the width Lₚ ranges from some nanometers to 20 nm or 200 nm.

FIG. 5 represents an oscillator 70 identical to the oscillator 60 except that the electrode 62 is replaced by an electrode 72 superimposed on a polarizer 74 and a spacer 76. For example, the polarizer 72 and the spacer 74 are identical respectively to the polarizer 52 and the spacer 54 except that their width Lₚ is several times smaller than the width L of the layers 8, 10 and 12. Typically, the ratio between the width Lₚ and the width L is identical to that described with reference to FIG. 4. For example, the width Lₚ is identical to that of the tip 64.

Many other embodiments of the radiofrequency oscillator are possible. For example, the above embodiments are described in the particular case where the free layer is made using a synthetic antiferromagnetic with three ferromagnetic sublayers. However, it is not necessary for the ferromagnetic sublayers to be sized so that their magnetic moments compensate for one another. Thus, as a variant, the stacking of the sublayers may simply form a synthetic ferromagnetic.

The synthetic ferromagnetic may comprise n ferromagnetic sublayers where n is an integer strictly greater than three. In practice, n is strictly smaller than ten. This embodiment of a synthetic ferromagnetic with more than three ferromagnetic sublayers is represented in FIG. 6 where:

FMᵢ designates the i^{th} ferromagnetic sublayer of the stack starting from the bottom, and

NMᵢ designates the i^{th} non-magnetic sublayer deposited between the ferromagnetic sublayers FMᵢ and FMᵢ₊₁.

At each time, the thickness of the sublayer NMᵢ is capable of creating an antiferromagnetic RKKY coupling between the sublayers FMᵢ and FMᵢ₊₁.

To increase the effective volume V_{eff} of the free layer without degrading the consistency of the magnetic precession, it is not necessary for the stack of ferromagnetic sublayers to constitute a synthetic ferrimagnetic. For example, as a variant, the synthetic ferrimagnetic described here above is replaced by a stack of ferromagnetic sublayers coupled to one another by an RKKY coupling, wherein:

at least two ferromagnetic sublayers, one immediately on top of the other, are coupled by a ferromagnetic RKKY coupling, and

at least two ferromagnetic sublayers, one immediately on top of the other, are coupled by an antiferromagnetic RKKY coupling.

The term “one immediately on top of the other” means that the two ferromagnetic sublayers are separated from each other solely by a non-magnetic sublayer shaped to create the desired RKKY coupling between the two ferromagnetic sublayers.

Once the stack comprises the two ferromagnetic sublayers coupled by a ferromagnetic RKKY coupling, it no longer constitutes a synthetic ferromagnetic with the definition given to it here.

For example, FIG. 7 is a stack 90 of four ferromagnetic sublayers 92 to 95 between which non-magnetic sublayers 98 to 100 are interposed. The thickness of the sublayer 98 is chosen so that the sublayers 92 and 93 are magnetically coupled by a ferromagnetic RKKY coupling. Similarly, the thickness of the sublayer 100 is chosen to obtain a ferromagnetic RKKY coupling between the sublayers 94 and 95. In FIG. 6, the direction of the magnetic moment of each ferromagnetic sublayer is represented by an arrow situated within the corresponding sublayer. The curved arrows shown outside the stack illustrate the direction of a few magnetic field lines.

Preferably, the stack 90 is compensated for, i.e. it is made so that its overall magnetic moment is equal to zero. To this end, it is possible to play on the volume of each ferromagnetic sublayer.

However, in order to improve the quality factor of the radiofrequency oscillator, it is not necessary to provide compensation for the synthetic ferromagnetic or for the stack 90 used.

The improvement in the quality factor of the radiofrequency oscillator occurs also if the reference layer is made with a synthetic ferrimagnetic or a stack of at least three ferromagnetic sublayers coupled by an RKKY coupling such as the stack 90. Thus, as a variant, to improve the quality factor, the reference layer and the free layer are both made with a stack of this kind. In another variant, only one of these two layers is made with one of the stacks described here above.

The polarizer can be trapped by a layer of antiferromagnetic material, but it can also be compensated for so as to have no measurable magnetization when there is no external magnetic field.

The order of stacking of the different layers of the oscillators described with reference to FIGS. 1 to 5 can be inverted relative to the stacking order shown.

The ferromagnetic layers or the ferromagnetic sublayers can be laminated as described in the patent application FR 2 892 871, for example on page 13 lines 1 to 10.

Preferably, only the ferromagnetic sublayer close to the layer forming the spacer is laminated.

As a variant, the difference in volume between the first sublayer closest to the spacer and one of the other sublayers is obtained by reducing at least one of the horizontal dimensions of the first sublayer.

It is also possible to introduce, into at least one of the ferromagnetic sublayers, a doping in the form of impurities based on rare earths, especially terbium, in proportions ranging from 0.01% to 2% (atomic percentage) so as to increase the consistency of precession.

More generally, in all the embodiments, the ferromagnetic sublayers may be replaced by ferromagnetic sublayers.

The ferromagnetic material implemented in at least one of the ferromagnetic or ferromagnetic sublayers preferably has a high constant of exchange stiffness. To this end, the invention implements 3d materials and especially cobalt or cobalt-rich alloys.

The ferromagnetic or ferrimagnetic sublayers can also be formed by a set of several ferromagnetic or ferrimagnetic strips, directly superimposed on one another for example as with NiFe/CoFe (both ferromagnetic) bi-layers or TbCo/CoFeB (both ferromagnetic) bi-layers commonly used in spin valves.

The magnetization of the reference layer can also be trapped by a magnetic field external to the pillar.

The free layer can also have a magnetization that precesses in the plane of the layer or outside the plane of the layer. The direction of the easier magnetization of the free layer can also be outside the plane of its layer and preferably perpendicular to its plane.

1. A radiofrequency oscillator integrating a magnetoresistive device within which a spin-polarized electrical current flows, said device comprising a stack of layers that includes:
a magnetic reference layer that is capable of causing a spin-polarized electrical current and that has a magnetization with a fixed direction,
a magnetic free layer having a magnetization that can oscillate when crossed by the spin-polarized current,
a non-magnetic spacer layer interposed between the two preceding layers and designed to magnetically uncouple said first and second magnetic layers, and
means for causing an electron current flow in said layers in a direction perpendicular to said layers,
wherein at least one of said free layer and said reference layer comprises a stack of at least three ferromagnetic or ferrimagnetic sublayers between which are interposed non-magnetic conductive sublayers,
wherein said ferromagnetic or ferrimagnetic sublayers are coupled to one another by RKKY (Ruderman-Kittel-Kasuya-Yosida) coupling, and
wherein at least two ferromagnetic or ferrimagnetic sublayers are magnetically coupled to one another by an antiferromagnetic RKKY coupling.

2. The oscillator according to claim 1, wherein each ferromagnetic or ferrimagnetic sublayer of the stack is coupled to the ferromagnetic or ferrimagnetic sublayer immediately above it by an antiferromagnetic RKKY coupling, whereby the stack comprises a synthetic ferrimagnetic.

3. The oscillator according to claim 2, wherein the sublayers are ferromagnetic sublayers and the magnetic moments of each ferromagnetic sublayer mutually compensate for one another, whereby the stack comprises a synthetic antiferromagnetic.

4. The oscillator according to claim 1, wherein
at least two ferromagnetic or ferrimagnetic sublayers are coupled to each other by an antiferromagnetic RKKY coupling, and
at least two ferromagnetic or ferrimagnetic sublayers are coupled to each other by a ferromagnetic RKKY coupling

5. The oscillator according to claim 1, wherein the stack of the ferromagnetic or ferrimagnetic sublayers consists of three ferromagnetic or ferrimagnetic sublayers.

6. The oscillator according to claim 1, wherein the thickness of a first ferromagnetic or ferrimagnetic sublayer closest to the non-magnetic layer is less than 10 nm.

7. The oscillator according to claim 6, wherein the thickness of a first ferromagnetic or ferrimagnetic sublayer closest to the non-magnetic layer is between 1 nm and 4 nm.

8. The oscillator according to claim 1, wherein at least the free layer comprises a stack of at least three ferromagnetic sublayers coupled to one another by an RKKY (Ruderman-Kittel-Kasuya-Yosida) coupling.

9. The oscillator according to claim 8, wherein the reference layer comprises a synthetic antiferromagnetic.

10. The oscillator according to claim 8, further comprising an antiferromagnetic layer in direct contact with the reference layer to trap the magnetization of the reference layer.

11. The oscillator according to claim 10, wherein the reference layer comprises a synthetic antiferromagnetic.
